(19) United States
(12) Patent Application Publication
(10) Pub. No.: US 2015/0059388 A1
(43) Pub. Date: Mar. 5, 2015

(54) INFORMATION PROCESSING APPARATUS

(71) Applicant: FUJITSU LIMITED, Kawasaki-shi (JP)

(72) Inventors: Yukihiro Hirano, Fucyu (JP); Keita Hirai, Kawasaki (JP); Akira Shimasaki, Kawasaki (JP); Keitaro KUROSAKI, Kawasaki (JP); Misao Umematsu, Kawasaki (JP)

(21) Appl. No.: 14/471,191

(22) Filed: Aug. 28, 2014

(30) Foreign Application Priority Data
Sep. 2, 2013 (JP) 2013-181481

(51) Int. Cl. H05K 7/20

(52) U.S. Cl. CPC H05K 7/2029
USPC 62/259.2

(57) ABSTRACT

An apparatus includes a cooling device that cools, by using refrigerant, heating components mounted over a circuit board and has different use-temperature conditions, wherein the circuit board is provided with a first area in which a first group of heating components having an operating condition of generating heat less than a given-heat quantity and operating in a temperature range lower than a first temperature is arranged, a second area in which a second group of heating components having an operating condition of generating heat equal not less than the given-heat quantity and operating in a temperature range between the first temperature and a second temperature exceeding the first temperature is arranged, and a third area in which a third group of heating components having an operating condition of generating heat equal to or less than the given-heat quantity and operating in a temperature range exceeding the second temperature is arranged.

### CROSS-REFERENCE TO RELATED APPLICATION

This application is based upon and claims the benefit of priority from the prior Japanese Patent Application No. 2013-181481 filed on Sep. 2, 2013, the entire contents of which are incorporated herein by reference.

### FIELD

The present disclosure relates to an information processing apparatus equipped with a cooling device that cools a heating component mounted over a circuit board using liquid refrigerant.

### BACKGROUND

Electronic elements such as a CPU or a control LSI are mounted on a main circuit board of a server device that is an information processing apparatus. These electronic elements generate heat at the time of being operated. Hence, in order to prevent the stable operation of the server device from being damaged by heat, it is necessary to cool the circuit board. As a cooling method, there has been proposed an air cooling system using a fan. However, the cooling method by a liquid cooling system using liquid refrigerant (“refrigerant”) is disclosed in patent document 1 and patent document 2, for example.

As the server devices require high performance as well as miniaturization and high-density packaging, the power consumption of the electronic elements is increased with the enhanced performance of the server devices. As a result, the electronic elements generate a large amount of heat and thus, the server devices are configured as follows so as to improve the cooling capacity of a cooling device that serves to cool the electronic elements.

In an air cooling system, it is necessary to send a lot of wind to the electronic elements so as to enhance the cooling capacity. Thus, in order to increase the flow of blown air, the air cooling system is configured to satisfy the following requirements.
Increasing the number of rotations of fans, the size of the fans, and the number of the fans.
Providing a duct for efficiently conveying cooling air.
Increasing the size of a heat sink that is installed in an electronic element part.

However, when these measures are implemented, the following problems may occur.
The increase of an air cooling space in the server device may negatively affect the high-density mounting of circuit components.
Since the electric power supplied to the fans increases, power capacity may increase and a power supply may be enlarged.
Securing of a heat sink space may inhibit miniaturization.
The increase of the heat sink space may suppress respective electronic elements from being disposed adjacent to each other.
Since wirings between the electronic elements are lengthened, high-speed signal transmission may be obstructed between CPUs or between a CPU and an interface.
Since the supply path between a power element and a CPU is lengthened, voltage drop may increase.
Since the increase of a power pattern and the installation of a bus bar or an electric wire are required, miniaturization and high-density mounting are obstructed.

In connection with the increase of heat quantity in a server device: a liquid cooling system having a relatively high cooling efficiency is used for an electronic element part generating a lot of heat, while an air cooling system is used for other parts. Further, in order to increase the cooling efficiency in the liquid cooling system, the refrigerant for a cooling body is supplied to a cooling plate (heat-exchange module) of a component via a pipe, and heated refrigerant is recovered via the pipe.

However, when the cooling plate is disposed above the electronic element generating a lot of heat and the refrigerant pipe is provided in the server device, the following problems may occur in terms of the miniaturization and high-density mounting in the server device.
Securing of a pipe space may inhibit the miniaturization of the server device.
Arrangement of electronic elements in the vicinity of a CPU may be obstructed in the pipe space.
Since the wiring pattern length between electronic elements is increased, the high-speed transmission of a signal may be obstructed.
A power element may not be arranged in the vicinity of a CPU, and the voltage drop of power may increase.

Therefore, there has been proposed a combined cooling system that combines a liquid cooling system using the cooling plate together with an air cooling system. FIG. 1A illustrates a conventional stand-alone device 90 provided with an air cooling system and a liquid cooling system. A plurality of CPU units 91 is mounted in the front side of the stand-alone device 90, and fans 92 and 93 for the air cooling system are provided in the rear side of the stand-alone device 90.

FIG. 2A illustrates an arrangement of an air cooling system 94 and a liquid cooling system 80 in the CPU unit 91 mounted in the stand-alone device 90 of FIG. 1A. A memory element 95 or a hiding CPU and an interface element are provided on a circuit board 96 of the CPU unit 91. The memory element 95 is cooled by cooling air CW of the air cooling system 94. The liquid cooling system 80 is provided with a cooling plate 83 configured to cool the CPU and a cooling plate 84 configured to cool the interface element, and the cooling plates are coupled to a refrigerant entrance 81 and a refrigerant exit 85 via a refrigerant pipe 82. The refrigerant entrance 81 and the refrigerant exit 85 are coupled to the cooling device 30 using the refrigerant illustrated in FIG. 1A.

FIG. 2B illustrates the cooling operation of the air cooling system 94 and the liquid cooling system 80 in the CPU unit 91 of FIG. 2A. In the air cooling system 94, the memory element 95 mounted over the circuit board 96 is cooled by the cooling air CW. The refrigerant pipe 82 of the liquid cooling system 80 is arranged in a direction orthogonal to the flowing direction of the cooling air CW. The refrigerant pipe 82 coupled to the refrigerant entrance 81 is provided with a refrigerant supply pipe 82A extending from one end to the other end of the circuit board 96, and a refrigerant recovery pipe 82B bent at the other end and returning to the refrigerant exit 85. In this example, the refrigerant supply pipe 82A and the refrigerant recovery pipe 82B have two systems, respectively.

A plurality of cooling plates 83 configured to cool the CPUs and a plurality of cooling plates 84 configured to cool the interface element are installed at predetermined positions on the refrigerant supply pipe 82A, whereas nothing is installed on the refrigerant recovery pipe 82B. After sequentially flowing through the plurality of cooling plates 83 to cool the CPUs and then sequentially flowing through the plurality of cooling plates 84 to cool the interface elements through the refrigerant supply pipe 82A, the refrigerant returns to the refrigerant exit 85 through the refrigerant recovery pipe 83B.

Patent Document 1: Japanese Patent Laid-Open Publication No. 2007-095902

Patent Document 2: Japanese Patent Laid-Open Publication No. 2004-266247

However, the cooling system using both the air cooling system 94 and the liquid cooling system 80 has the following problems.
A pipe arrangement that does not disturb the flow of cooling air is required, and, when the refrigerant pipe is arranged to float from the circuit board to keep off the cooling air, an optimum piping route for the refrigerant may not be secured.
As for the electronic component to be cooled by the air cooling system, since an arrangement considering a duct is required, optimum mounting may be obstructed.

### SUMMARY

According to an aspect of the embodiments, an information processing apparatus includes: a cooling device configured to cool, by using refrigerant, heating components mounted over a circuit board and having different use temperature conditions, wherein the circuit board is provided with a first area in which a first group of heating components having an operating condition of generating heat less than a given heat quantity and operating in a temperature range lower than a first temperature is arranged, a second area in which a second group of heating components having an operating condition of generating heat equal to or more than the given heat quantity and operating in a temperature range between the first temperature and a second temperature exceeding the first temperature is arranged, and a third area in which a third group of heating components having an operating condition of generating heat equal to or less than the given heat quantity and operating in a temperature range exceeding the second temperature is arranged.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a perspective view illustrating a conventional stand-alone device provided with an air cooling system and a liquid cooling system;

FIG. 1B is a perspective view illustrating an external appearance of an information processing apparatus according to the present disclosure;

FIG. 2A is a perspective view illustrating an arrangement of an air cooling system and a liquid cooling system in a CPU unit mounted in the stand-alone device of FIG. 1A;

FIG. 2B is a plan view illustrating the operation of the air cooling system and the liquid cooling system in the CPU unit illustrated in FIG. 2A;

FIG. 3A is a perspective view illustrating an internal configuration of a CPU module mounted in the information processing apparatus of FIG. 1B;

FIG. 3B is an assembled perspective view illustrating an arrangement of three CPUs and a liquid cooling system corresponding thereto in one CPU device mounted in the CPU module of FIG. 3A;

FIG. 4A is a plan view illustrating a state after the assembly of the CPU device illustrated in FIG. 3B;

FIG. 4B is a sectional view taken along line A-A of FIG. 4A;

FIG. 5A is a system view illustrating the flow of refrigerant in the liquid cooling system mounted in the CPU device of FIG. 4A;

FIGS. 5B to 5E are sectional views illustrating exemplary embodiments of sectional shapes of a refrigerant supply pipe and a refrigerant recovery pipe that may be used in the cooling system of the information processing apparatus according to the present disclosure;

FIG. 6 is a system view illustrating the flow of refrigerant in a liquid cooling system mounted in the CPU device equipped with four CPUs, and a connection with the refrigerant cooling device that supplies the refrigerant to the CPU device;

FIG. 7A is a system view illustrating a structure of a liquid cooling system corresponding to another CPU arrangement in the CPU device of FIG. 3A;

FIG. 7B is a system view illustrating a structure of a liquid cooling system corresponding to a further CPU arrangement in the CPU device of FIG. 3A;

FIG. 8A is a system view illustrating a modified embodiment of piping in the liquid cooling system of FIG. 6;

FIG. 8B is a system view illustrating a modified embodiment of piping in the liquid cooling system of FIG. 7A;

FIG. 9A is a system view illustrating a first exemplary embodiment of a refrigerant stirring mechanism in the refrigerant supply pipe and the refrigerant recovery pipe of the liquid cooling system illustrated in FIG. 5;

FIG. 9B is a partially enlarged view illustrating the portion B in FIG. 9A;

FIG. 9C is a partially enlarged view illustrating a modified embodiment of the stirring structure according to the first exemplary embodiment;

FIG. 10A is a system view illustrating a second exemplary embodiment of a refrigerant stirring mechanism of a refrigerant conduit in the liquid cooling system of FIG. 5;

FIG. 10B is a partially enlarged perspective view illustrating the portion C in FIG. 10A; and

FIG. 10C is a partially enlarged perspective view illustrating a modified embodiment of the stirring structure according to the second exemplary embodiment.

### DESCRIPTION OF EMBODIMENTS

Hereinafter, aspects of the present disclosure will be described in detail on the basis of specific exemplary embodiments with reference to drawings. In the description of exemplary embodiments described below, an optical communication device provided with an optical interface element, a CPU and a power element will be described as an information processing apparatus. However, the information processing apparatus is not limited to the optical communication device and the present disclosure may be applied to other information processing apparatuses than the optical communication device.

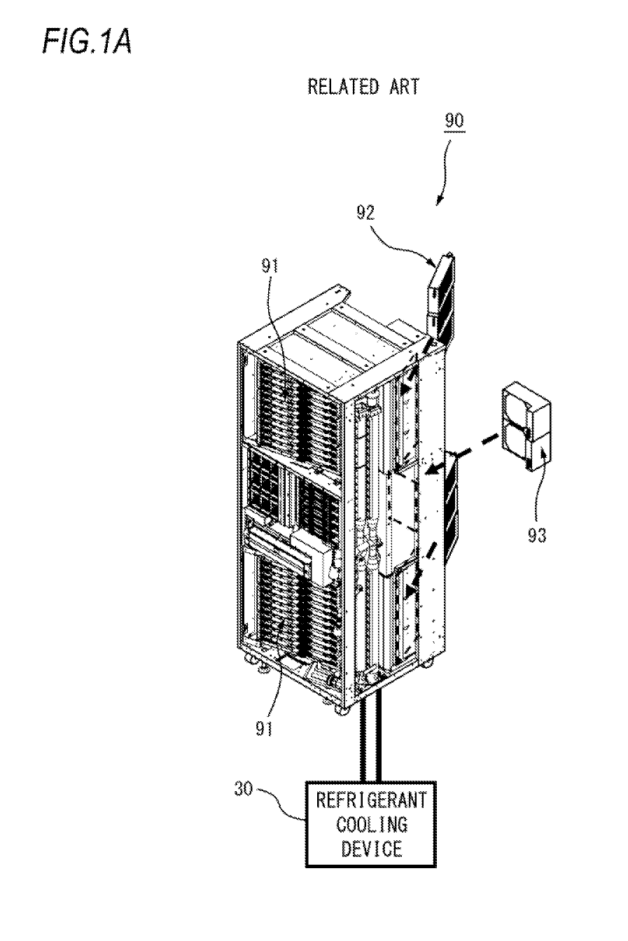

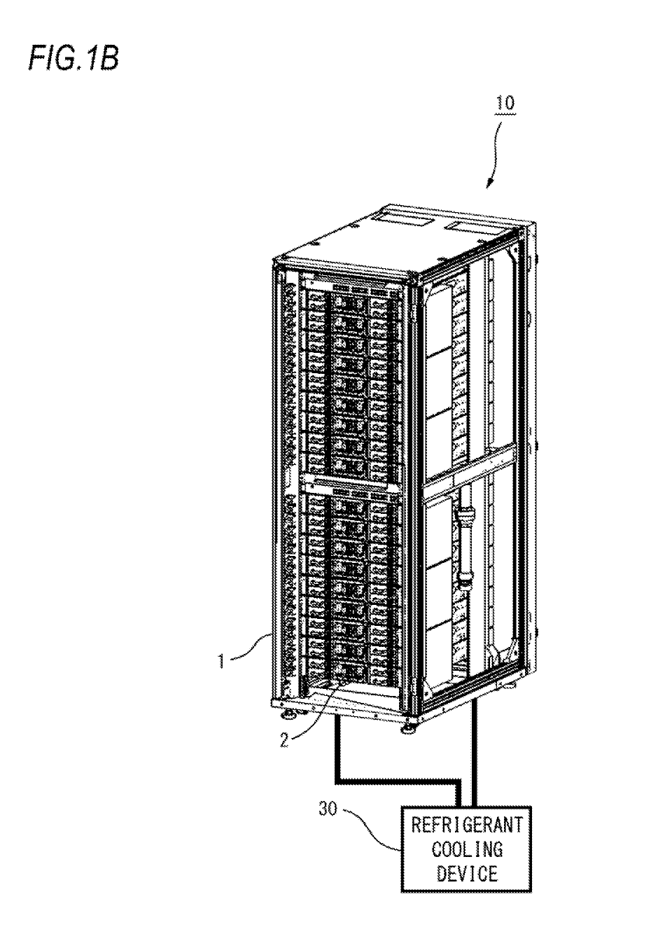

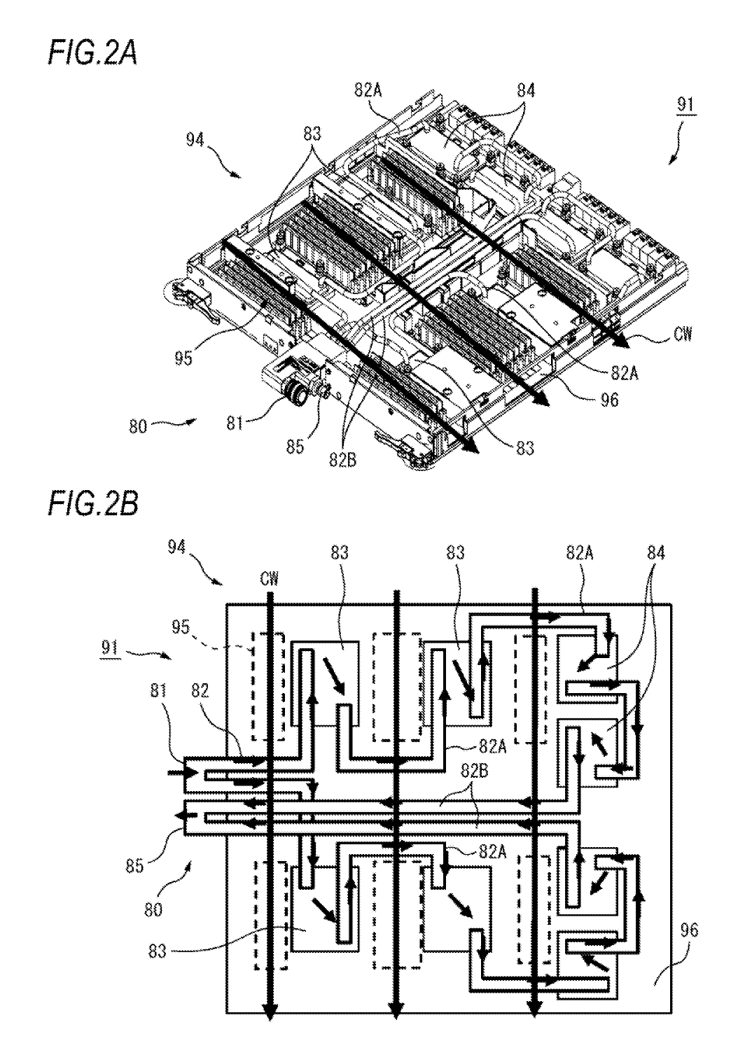

FIG. 1B illustrates an external appearance of an information processing apparatus 10 according to an exemplary embodiment of the present disclosure, and illustrates a server device for an optical communication. In the information processing apparatus 10 of the present exemplary embodiment, a plurality of CPU modules 2 is provided in a rack 1. In the present exemplary embodiment, all of the CPU modules 2 provided in the rack 1 of the information processing apparatus 10 according to the present exemplary embodiment is cooled by a liquid cooling system. However, the information processing apparatus 10 is not equipped with the cooling device for cooling the refrigerant of the liquid cooling system. The refrigerant cooling device is installed in another place and supplies the refrigerant to the plurality of CPU modules 2.

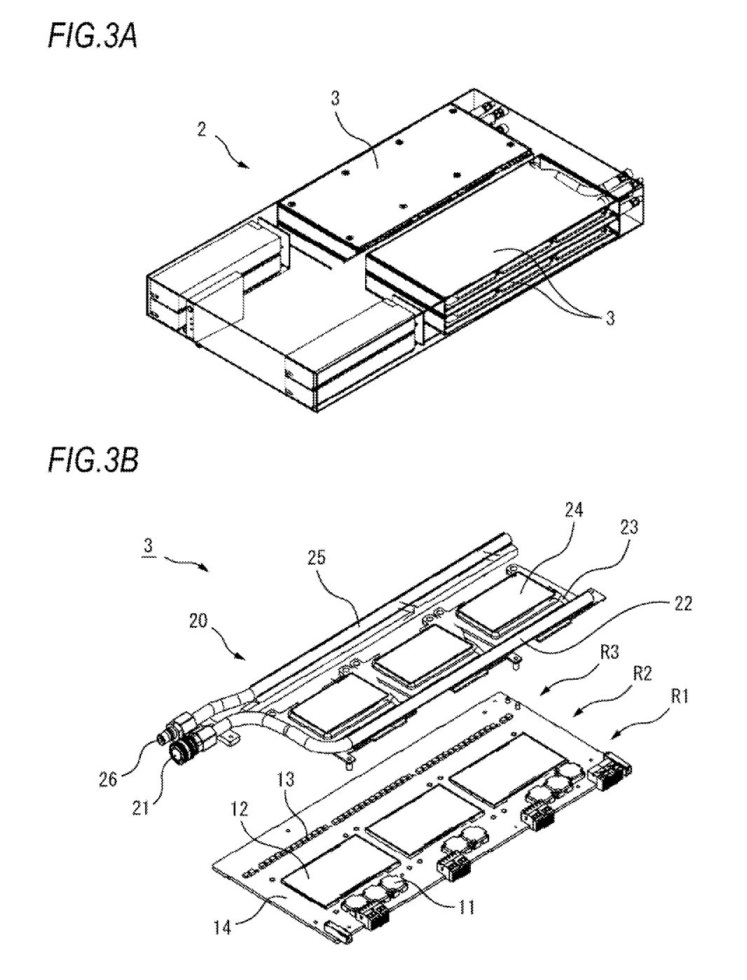

FIG. 3A illustrates the internal configuration of the CPU module 2 mounted in the information processing apparatus of FIG. 1B. According to the present exemplary embodiment, four CPU devices 3 are installed in the CPU module 2. FIG. 3B illustrates the internal configuration of the CPU device 3 illustrated in FIG. 3A. Since the information processing apparatus 10 of the present exemplary embodiment is an optical communication device, optical interface elements 11, CPUs 12, and power elements 13 are disposed on a circuit board 14 installed in the CPU device 3.

Here, the temperature use conditions of the optical interface elements 11, the CPUs 12 and the power elements 13 installed in the information processing apparatus 10 for optical communication are considered. The optical interface elements 11 are low heating and low temperature components having a temperature use condition in which the heating range is 15W to 25W and the use temperature condition is 20° C. to 40° C. The CPUs 12 are high heating and middle temperature components having a temperature use condition in which the heating range is 200W to 300W and the use temperature condition is 20° C. to 60° C. Further, the power elements 13 are low heating and high temperature components having a temperature use condition in which the heating range is 15W to 25W and the use temperature condition is 20° C. to 80° C.

According to the present disclosure, the component mounting area of the circuit board 14 is divided into, for example, three (3) areas, namely, a first area R1, a second area R2 and a third area R3 in a row form in the longitudinal direction of the circuit board 14. Further, electronic elements are grouped according to the temperature use conditions and each group is arranged in one of the three divided areas R1 to R3. For example, the optical interface elements 11 may be arranged in the vicinity of the CPUs 12 so as to reduce the length of a signal line, thus enabling high-speed transmission. Further, the power elements 13 may be arranged in the vicinity of the CPUs so as to minimize a voltage drop by power feeding.

In view of the above use conditions, for example, in the present exemplary embodiment, three CPUs 12 are arranged in the second area R2 that is located in the center of the circuit board 14, and a plurality of interface elements 11 and power elements 13 are arranged, respectively, in the first and third areas R1 and R3 adjacent to the second area R2. Further, according to the present disclosure, the air cooling system is not used but refrigerant piping of the liquid cooling system 20 is used so as to cool the optical interface elements 11, the CPUs 12, and the power elements 13 which are mounted over the circuit board 14. Hereinafter, the cooling structure using the refrigerant piping of the liquid cooling system 20 will be described.

The liquid cooling system 20 includes: a refrigerant supply pipe 22 provided with a refrigerant entrance 21; connection pipes 23 provided with cooling plates 24 configured to cool the CPUs 12, on predetermined portions thereof; and a refrigerant recovery pipe 25 configured to return refrigerant, which has been returned from the cooling plates 24 through the connection pipes 23, to a refrigerant exit 26. The refrigerant entrance 21 and the refrigerant exit 26 are coupled to a cooling device configured to recover, cool, and circulate the refrigerant whose temperature has risen. The refrigerant supply pipe 22 is disposed immediately above the optical interface element 11 along the first area R1 of the circuit board 14. The cooling plates 24 are heat-exchange modules, and are disposed immediately above the CPUs 12 mounted over the second area R2 of the circuit board 14. The refrigerant recovery pipe 25 is disposed immediately above the power element 13 along the third area R3 of the circuit board 14. The connection pipe 23 connects the refrigerant supply pipe 22 to each of the cooling plates 24, and connects each of the cooling plates 24 to the refrigerant recovery pipe 25.

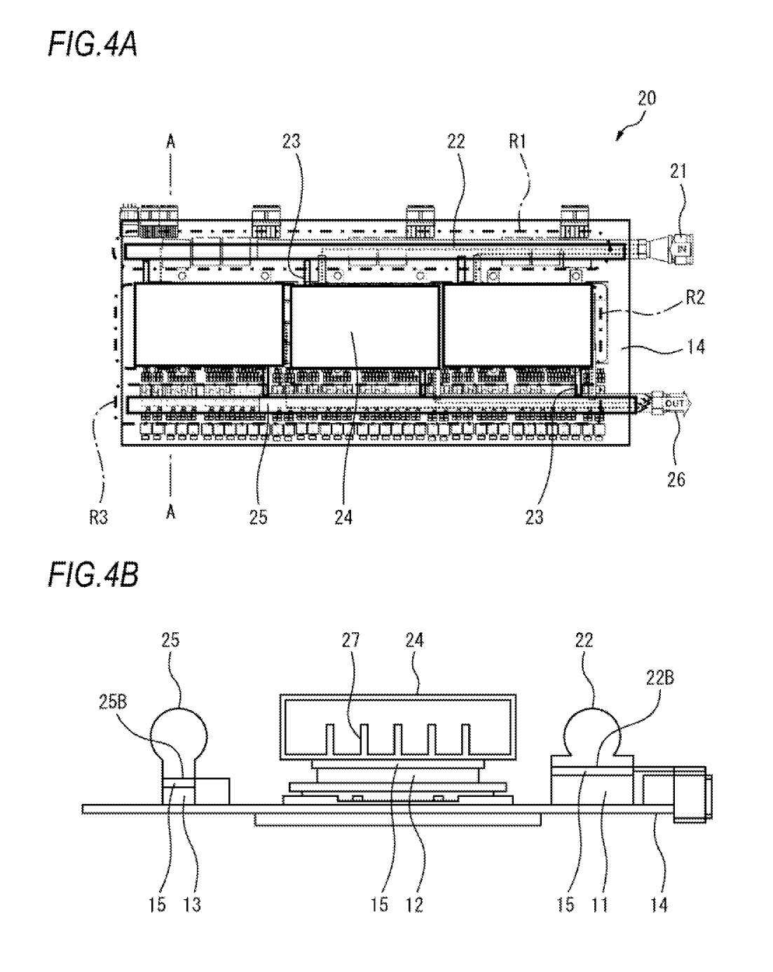

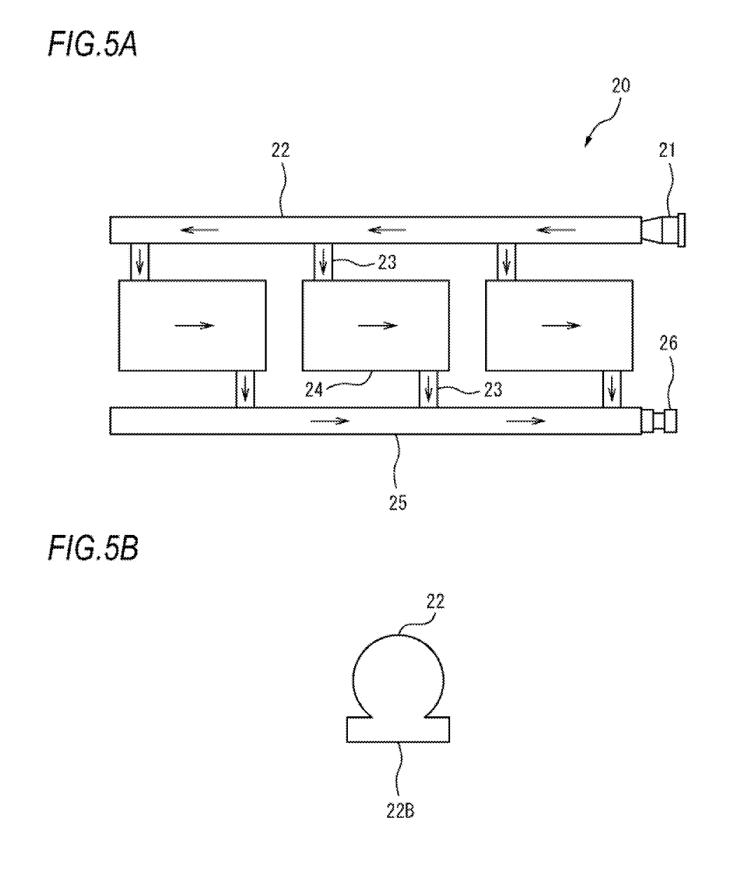

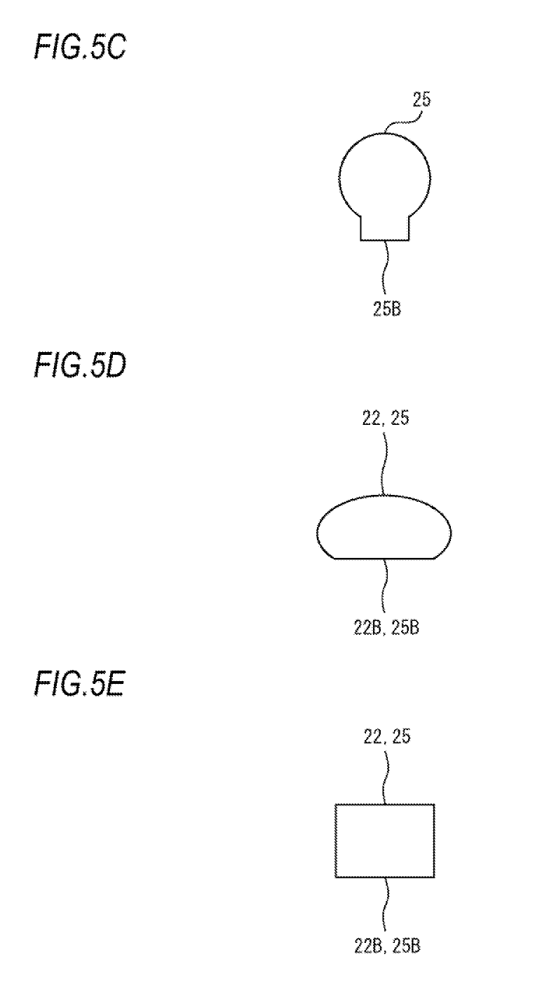

FIG. 4A illustrates a state where the liquid cooling system 20 is placed on the circuit board 14 illustrated in FIG. 3B. In the liquid cooling system 20 of FIG. 3B, the refrigerant entrance 21 and the refrigerant exit 26 are arranged to be adjacent to each other. However, in the exemplary embodiment of FIG. 4A, the refrigerant entrance 21 and the refrigerant exit 26 are located to be spaced apart from each other. FIG. 4B illustrates a sectional view taken along line A-A of FIG. 4A, and FIG. 5A illustrates the direction of the refrigerant flowing in the refrigerant supply pipe 22, the connection pipes 23, the cooling plates 24, and the refrigerant recovery pipe 25 illustrated in FIG. 4A.

As illustrated in FIG. 4B, a cooling plate 24 is disposed immediately above a CPU, and is joined to the CPU 12 using a thermal sheet 15. A plurality of fins 27 protrudes inside the cooling plate 24 so as to improve heat exchange efficiency when the refrigerant flows in the cooling plate 24 in a meandering manner. Lower surfaces 22B and 25B of the refrigerant supply pipe 22 and the refrigerant recovery pipe 25 disposed immediately above the optical interface element 11 and the power element 13 are formed as flat surfaces so as to efficiently perform heat exchange with the optical interface element 11 and the power element 13. The optical interface element 11 and the bottom surface 22B of the refrigerant supply pipe 22 are joined to each other using the thermal sheet 15, and the power element 13 and the bottom surface 25B of the refrigerant recovery pipe 25 are also joined to each other using the thermal sheet 15.

The conventional refrigerant supply pipe and refrigerant recovery pipe have the function of merely conveying the refrigerant. According to the present disclosure, the bottom surface 22B of the refrigerant supply pipe 22 is formed as a flat surface to be disposed on the optical interface element 11 via, for example, the thermal sheet 15, grease, and a spring such that the heat generated by the optical interface element 11 is cooled by the refrigerant supply pipe 22. Likewise, the bottom surface 25B of the refrigerant recovery pipe 25 is formed as a flat surface to be disposed on the power element 13 via, for example, the thermal sheet 15, the grease, and the spring such that the heat generated by the power element 13 is cooled by the refrigerant recovery pipe 25. The refrigerant supply pipe 22 and the refrigerant recovery pipe 25 are made of a material having high heat conductivity. Thus, in the information processing apparatus of the present disclosure, the air cooling system is not required. Further, when the thickness of the thermal sheet is adjusted, the height difference between the heating component and the refrigerant supply pipe 22 or the refrigerant recovery pipe 25 may be absorbed

FIGS. 5B and 5C illustrate the cross-sections of the refrigerant supply pipe 22 and the refrigerant recovery pipe 25 in which the bottom surfaces 22B and 25B are formed as flat surfaces as illustrated in FIG. 4B. The flat surfaces formed on the bottom surfaces 22B and 25B of the refrigerant supply pipe 22 and the refrigerant recovery pipe 25 may be aligned with the top surfaces of heating elements. FIGS. 5D and 5E illustrate the cross-sectional shapes of the refrigerant supply pipe 22 and the refrigerant recovery pipe 25 according to other exemplary embodiments, in which the bottom surfaces 22B and 25B applicable to the refrigerant supply pipe 22 and the refrigerant recovery pipe 25 are formed as flat surfaces.

When the liquid cooling system 20 is configured as described above, the optical interface element 11 located immediately below the refrigerant supply pipe 22 is cooled by the refrigerant that is supplied from the refrigerant entrance 21 and flows in the refrigerant supply pipe 22, as illustrated in FIG. 5A. The CPUs 12 located immediately below the cooling plates 24 are cooled by the refrigerant which is split into three branches by the connection pipes 23 and then flows in the cooling plates 24. In addition, the power elopements located immediately below the refrigerant recovery pipe 25 are cooled by the refrigerant which returns to the connection pipes 23, flows in the refrigerant recovery pipe 25 and then returns to the refrigerant exit 26. Although the temperature of the refrigerant flowing in the refrigerant recovery pipe 25 rises, the power elements 13 located immediately below the refrigerant recovery pipe 25 may be cooled by the refrigerant of which the temperature has risen since the power elements 13 are electronic components having a use condition of a low heating and high temperature range.

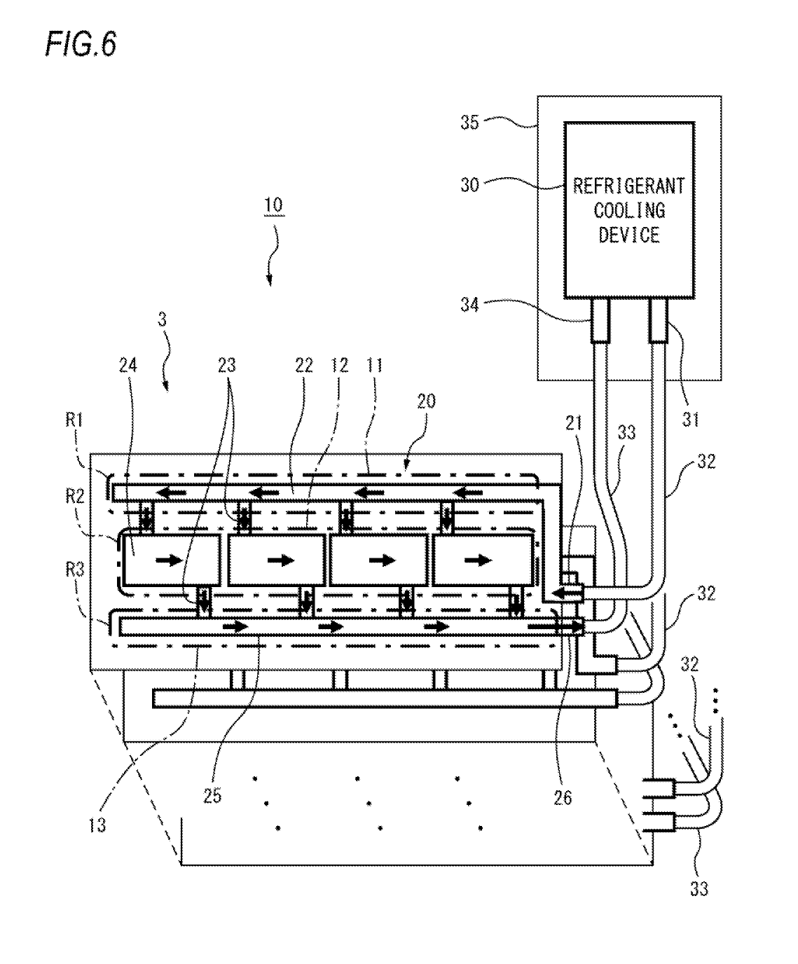

FIG. 6 illustrates the flow of refrigerant in the liquid cooling system 20 installed in a CPU device 3 equipped with four CPUs 12 and a connection with the refrigerant cooling device 30 that supplies the refrigerant to the CPU device 3. As described above, the refrigerant cooling device 30 is installed in a housing 35 provided outside the information processing apparatus 10, and discharges the refrigerant having a low temperature from an outlet port 31 so as to supply the refrigerant through a distribution pipe 32 to each of the liquid cooling systems 20 of a plurality of CPU devices 3 installed in the information processing apparatus 10. The refrigerant of which the temperature has risen in in each CPU device 3 is collected through a return pipe 33 and then returns to an inlet port 34. The refrigerant cooling device 30 cools the refrigerant in a main body and then discharges the refrigerant from the outlet port 31 again.

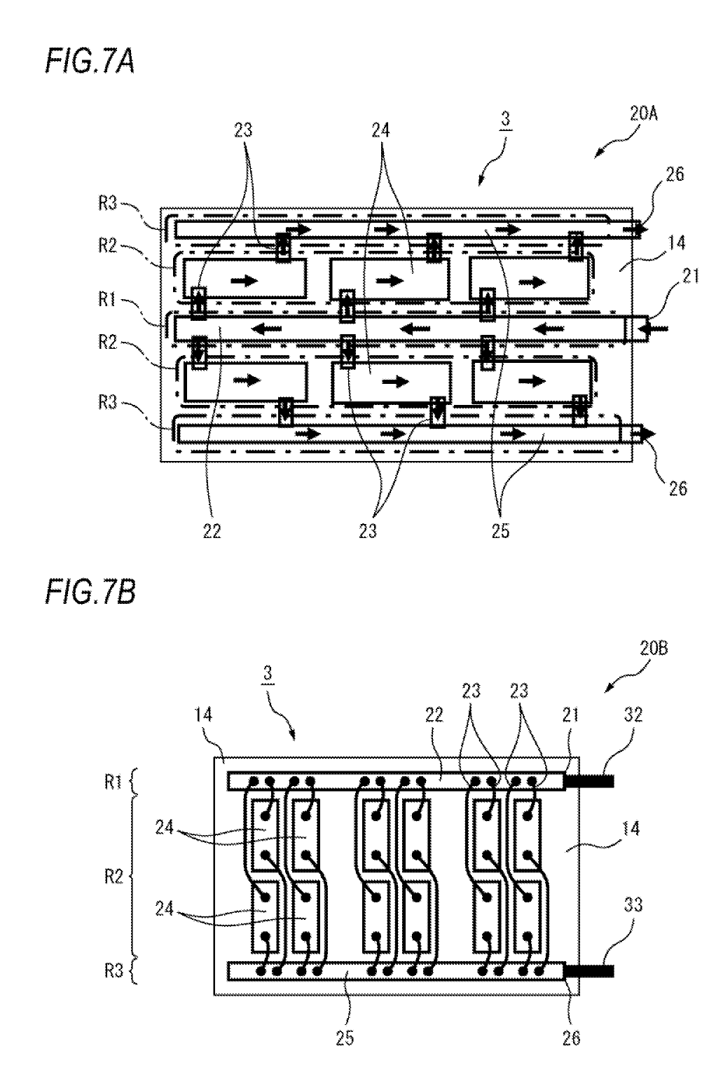

FIG. 7A is a system view illustrating the structure of an exemplary embodiment of a liquid cooling system 20A corresponding to an additional CPU arrangement in the CPU device 3 of FIG. 3A. In the present exemplary embodiment, the circuit board 14 is divided into a plurality of areas in a row form in the longitudinal direction thereof. Unlike the above-mentioned exemplary embodiment, five (5) areas exist in the present exemplary embodiment. In the present exemplary embodiment, the central area of the circuit board 14 is a first area R1 in which a plurality of optical interface elements are disposed, and second areas R2 are provided on both sides of the first area R1 in which three CPUs are disposed. Third areas R3 are provided outside the respective second areas R2, and the power element is disposed in each of the third area R3.

In the case of the liquid cooling system 20A illustrated in FIG. 7A, a refrigerant supply pipe 22 is disposed in the first area which is provided at the center of the circuit board 14, and cooling plates 24 corresponding to the number of CPUs are disposed on the opposite sides of the refrigerant supply pipe 22. Each cooling plate 24 is coupled to the refrigerant supply pipe 22 via the connection pipes 23 so that the refrigerant discharged from each cooling plate 24 returns to the two refrigerant recovery pipes 25 disposed at both ends of the circuit board 14 via the connection pipe 23. Although the refrigerant exits 26 provided at two places are not illustrated in the drawing, refrigerant discharged therefrom meets and returns to the refrigerant cooling device 30 illustrated in FIG. 6.

FIG. 7B is a system view illustrating the structure of an exemplary embodiment of a liquid cooling system 20B corresponding to another CPU arrangement in the CPU device 3 of FIG. 3A. In the present exemplary embodiment, the circuit board 14 is divided into three areas in a row form in the longitudinal direction thereof, similarly to the above-described exemplary embodiment. However, the present exemplary embodiment is different from the above-described exemplary embodiment in that the second area R2 is wide and six (6) CPUs are aligned in two rows in the second area R2. The positions of the first area R1 and the third area R3 with respect to the second area R2 are the same as those of the above-described exemplary embodiment. The first area R1 is on one side of the second area R2, while the third area R3 is on the other side of the second area R2.

In the liquid cooling system 20B of FIG. 7B, connection pipes 23 are coupled to twelve (12) cooling plates 24 from a refrigerant supply pipe 22, respectively, so that the refrigerant discharged from the cooling plates 24 returns to the refrigerant recovery pipe 25 via the respective connection pipes 23. The present exemplary-embodiment is the same as the above-described exemplary embodiment in that the optical interface elements are cooled on the bottom surface of the refrigerant supply pipe 22, the CPUs are cooled by the cooling plates 24, and the power elements are cooled on the bottom surface of the refrigerant recovery pipe 25. Reference numeral 32 denotes a refrigerant distribution pipe, and reference numeral 33 denotes a refrigerant return pipe.

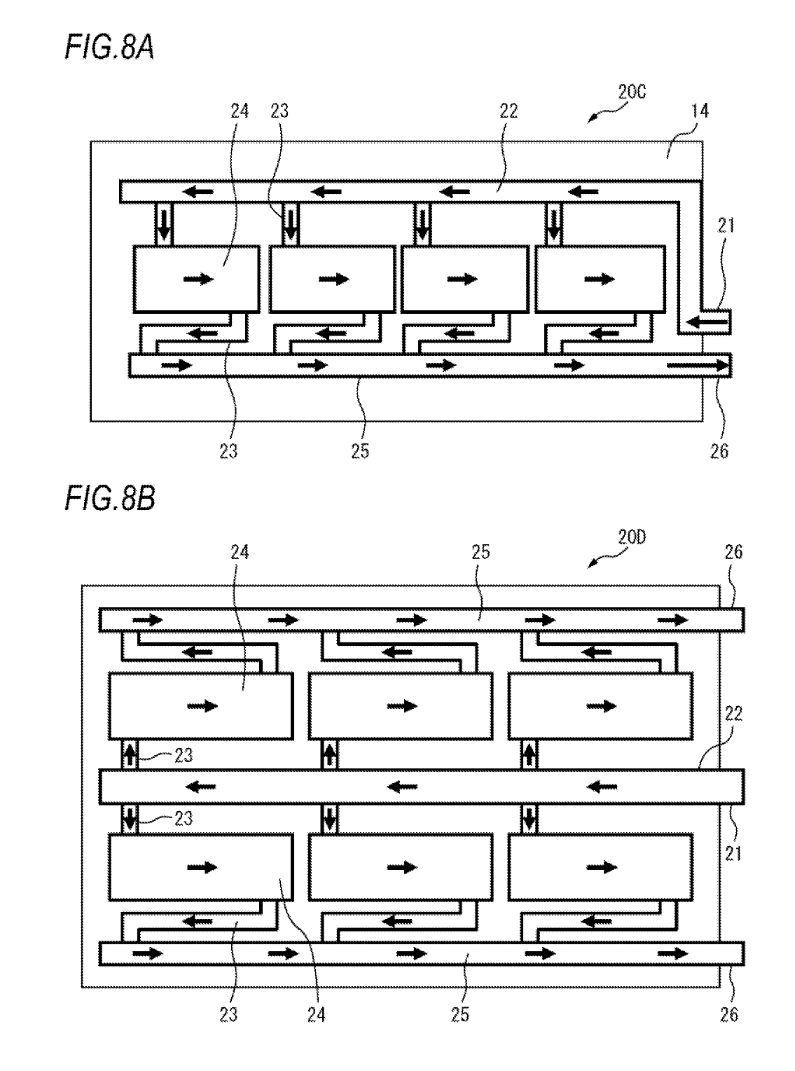

FIG. 8A is a system view illustrating a liquid cooling system 20C according to a modified embodiment where the connection of the connection pipe 23 in the liquid cooling system 20 of FIG. 6 is changed. In the liquid cooling system 20 of FIG. 6, the connection pipes 23 connect the cooling plates 24 to the refrigerant recovery pipe 25 at the shortest distance. Meanwhile, in the liquid cooling system 20C of the modified embodiment illustrated in FIG. 8A, the length of the connection pipes 23 connecting the cooling plates 24 to the refrigerant recovery pipe 25 is increased so that the connection pipes 23 are coupled to an upstream side of the refrigerant flow of the refrigerant recovery pipe 25. Consequently, the flow of the refrigerant in the refrigerant recovery pipe 25 is increased and, thus, the refrigerant is capable of cooling more power elements as compared with those on the circuit board 14.

FIG. 8B is a system view illustrating a liquid cooling system 20D according to a modified embodiment where the connection of the connection pipe 23 in the liquid cooling system 20A illustrated in FIG. 7A is changed. In the liquid cooling system 20A of FIG. 7A, the connection pipes 23 connect the cooling plates 24 to the refrigerant recovery pipe 25 at the shortest distance. Meanwhile, in the liquid cooling system 20D of FIG. 8B according to the modified embodiment, the length of the connection pipes 23 connecting the cooling plates 24 to the refrigerant recovery pipe 25 is increased so that the connection pipes 23 are coupled to the upstream side of the refrigerant flow of the refrigerant recovery pipe 25. Consequently, the flow of the refrigerant in the refrigerant recovery pipe 25 is increased and, thus, the refrigerant is capable of cooling more power elements as compared with those on the circuit board 14.

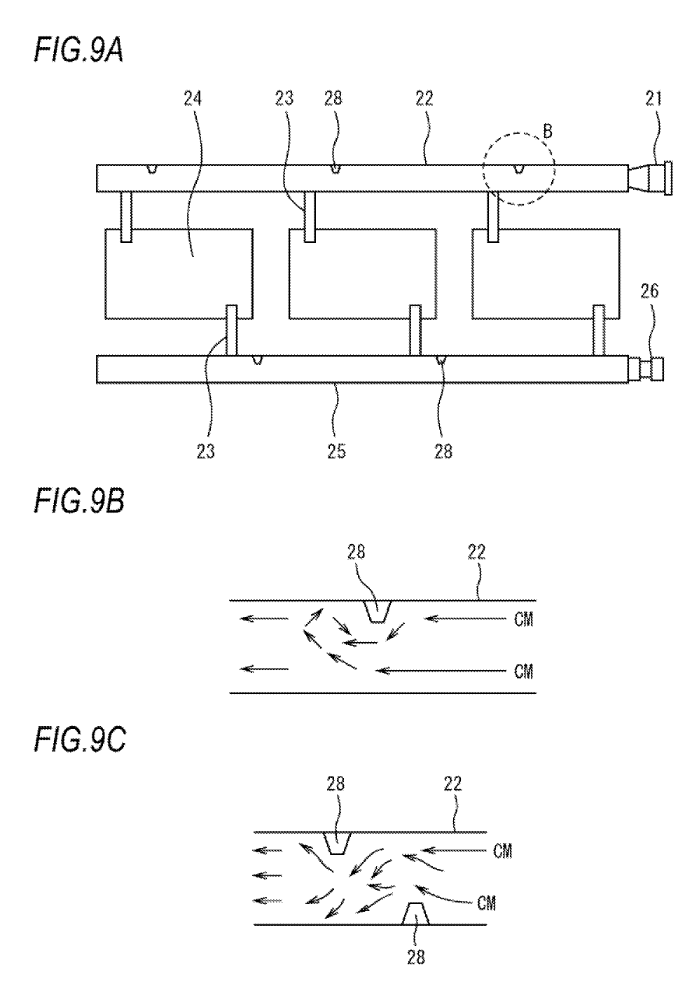

FIG. 9A illustrates a first exemplary embodiment of a refrigerant stirring mechanism in the refrigerant supply pipe 22 and the refrigerant recovery pipe 25 of the liquid cooling system 20 illustrated in FIG. 5A. As described above, the bottom surfaces 22B and 25B of the refrigerant supply pipe 22 and the refrigerant recovery pipe 25 are flat surfaces, and absorb the heat generated by the optical interface elements and the power elements. Thus, the temperature of the refrigerant flowing in the refrigerant supply pipe 22 and the refrigerant recovery pipe 25 gradually rises. Here, the temperature of the refrigerant near to the bottom surfaces 22B and 25B of the refrigerant supply pipe 22 and the refrigerant recovery pipe 25 becomes higher than the temperature of the refrigerant distant from the bottom surfaces 22B and 25B. Consequently, the cooling efficiency of the optical interface elements and the power elements by the refrigerant is deteriorated.

As illustrated in FIG. 9A, the refrigerant is stirred at predetermined positions in each of the refrigerant supply pipe 22 and the refrigerant recovery pipe 25 so as to lower the temperature of the refrigerant near to the bottom surfaces 22B and 25B of the refrigerant supply pipe 22 and the refrigerant recovery pipe 25. FIG. 9B is a partially enlarged view illustrating the portion B in FIG. 9A in which a convex portion 28 is provided at a predetermined position in the conduit. When the convex portion 28 is provided at a predetermined position in the conduit in this manner, the refrigerant CM flowing in the conduit is stirred by the convex portion 28. Thus, the temperature of the refrigerant CM in the conduit becomes uniform, and the temperature of the refrigerant CM near to the bottom surfaces 22B and 25B of the refrigerant supply pipe 22 and the refrigerant recovery pipe 25 decreases. Consequently, the cooling efficiency of the optical interface element and the power element by the refrigerant CM is enhanced. In the first exemplary embodiment, the convex portion 28 is provided on one side in the conduit of each of the refrigerant supply pipe 22 and the refrigerant recovery pipe 25. However, as in the modified embodiment of FIG. 9C, convex portions 28 may be provided on both sides in the conduit. The convex portions 28 are not limited to a particular shape.

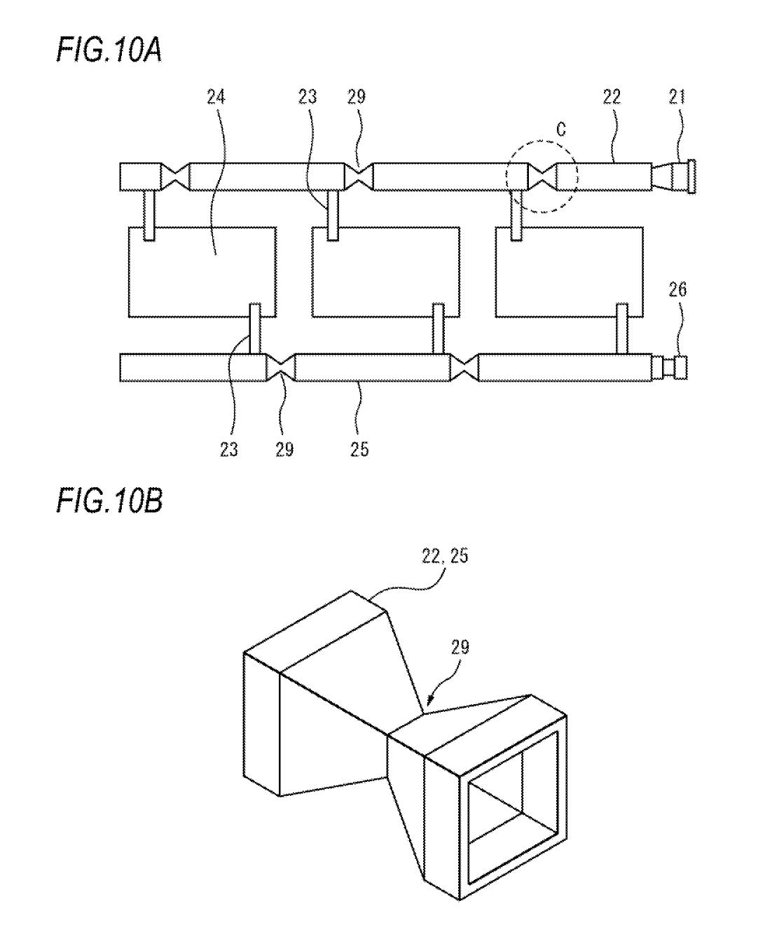

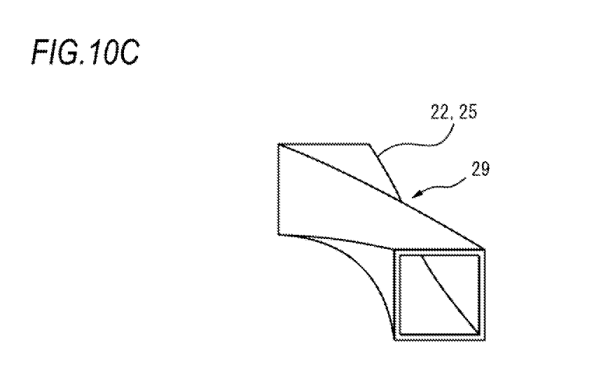

FIG. 10A illustrates a second exemplary embodiment of a refrigerant stirring mechanism in the refrigerant supply pipe 22 and the refrigerant recovery pipe 25 of the liquid cooling system 20 illustrated in FIG. 5A. In the first exemplary embodiment, the convex portions 28 are provided at predetermined positions in the conduit of each of the refrigerant supply pipe 22 and the refrigerant recovery pipe 25 to stir the refrigerant CM so as to lower the temperature of the refrigerant CM near to the bottom surfaces 22B and 25B of the refrigerant supply pipe 22 and the refrigerant recovery pipe 25. Meanwhile, in the second exemplary embodiment of FIG. 10A, throttle portions 29 are provided at predetermined positions in the conduit to reduce the sectional area of the flow path in the conduit.

When the sectional area of the flow path is reduced by the throttle portions 29, the refrigerant CM is stirred when the refrigerant CM has passed through the throttle portions 29. Thus, when the throttle portions 29 are provided at predetermined positions in the conduit, the refrigerant CM flowing in the conduit is stirred after passing through the throttle portions 29. Thus, the temperature of the refrigerant CM in the conduit becomes uniform, and the temperature of the refrigerant CM near to the bottom surfaces 22B and 25B of the refrigerant supply pipe 22 and the refrigerant recovery pipe 25 decreases. Consequently, the cooling efficiency of the optical interface element and the power element by the refrigerant CM is enhanced.

FIG. 10B is a partially enlarged view illustrating the portion C in FIG. 10A. In this exemplary embodiment, the conduit of each of the refrigerant supply pipe 22 and the refrigerant recovery pipe 25 has a rectangular cross-section. In this case, each side of the conduit of each of the refrigerant supply pipe 22 and the refrigerant recovery pipe 25 is narrowed and then widened to the original shape. FIG. 10C illustrates a modified embodiment of the stirring structure of the second exemplary embodiment. In this modified embodiment, the conduit of each of the refrigerant supply pipe 22 and the refrigerant recovery pipe 25 also has a rectangular cross-section. According to present modified embodiment, respective sides of the conduit of each of the refrigerant supply pipe 22 and the refrigerant recovery pipe 25 are twisted in the same direction by 90° so as to form a throttle portion 29. In the modified embodiment of the second exemplary embodiment, since the conduit is turned by 90° in addition to being narrowed, the refrigerant may be well stirred after passing through the throttle portion 29.

The stirring structures illustrated in FIGS. 9A to 9C and FIGS. 10A to 10C are merely examples. In addition to such structures, a propeller may be installed in the conduit, and a fin causing a flow to be disturbed may be provided. In the refrigerant supply pipe 22, the stirring structures may be located at the upstream side of the connection portion of each connection pipe 23 in the refrigerant supply pipe 22, and, in the refrigerant recovery pipe 25, the structures may be located at the downstream side of the connection portion of each connection pipe 23 in the refrigerant recovery pipe 25.

As described above, according to the present disclosure, a piping space of a circuit board is reduced, thereby enabling the miniaturization and high-density mounting of the board. Since an optical interface element or a power element may be located in the vicinity of a CPU, a wiring may be shortened such that high-speed communication may be realized, a voltage drop may be reduced, and the number of power components may be reduced. In addition, since it is not necessary to consider air flow, the flexibility in arranging components may be improved such that the optimum mounting of the components is enabled. Furthermore, since refrigerant piping may also be used for a cooling function, the optimum mounting of cooling components may be realized with a simple arrangement.

Hereinbefore, the present disclosure has been described in detail with reference to the exemplary embodiments.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the embodiment(s) of the present invention has (have) been described in detail, it should be understood that the various changes, substitutions, and alterations could be made hereto without departing from the spirit and scope of the invention.

What is claimed is:

1. An information processing apparatus, comprising:
a cooling device configured to cool, by using refrigerant, heating components mounted over a circuit board and having different use temperature conditions, wherein the circuit board is provided with a first area in which a first group of heating components having an operating condition of generating heat less than a given heat quantity and operating in a temperature range lower than a first temperature is arranged, a second area in which a second group of heating components having an operating condition of generating heat equal to or more than the given heat quantity and operating in a temperature range between the first temperature and a second temperature exceeding the first temperature is arranged, and a third area in which a third group of heating components having an operating condition of generating heat equal to or less than the given heat quantity and operating in a temperature range exceeding the second temperature is arranged;
a first refrigerant flow path coupled to an inlet port of the refrigerant is arranged along the first area;
a third refrigerant flow path coupled to an outlet port of the refrigerant is arranged along the third area;
a plurality of connection flow paths are provided between the first refrigerant path and third refrigerant path to allow the refrigerant to flow from the first refrigerant flow path to the third refrigerant flow path;
heat exchange modules are correspondingly provided at predetermined positions in the connection flow paths to cool the second group of heating components.

2. The information processing apparatus of claim 1, wherein the first area, the second area and the third area are provided in this order on the circuit board to be arranged in a row form.

3. The information processing apparatus of claim 1, wherein the third area, the second area, the first area, the second area, and the third area are provided in this order on the circuit board to be arranged parallel in a row form.

4. The information processing apparatus of claim 2, wherein the heat exchange modules are provided along the second area between the first and third refrigerant flow paths to be arranged parallel in two rows, and the heat exchange modules arranged parallel in two rows are connected, via the connection flow paths, to the first and third refrigerant flow paths, respectively.

5. The information processing apparatus of claim 1, wherein at least one stirring structure is provided at a predetermined position in each of the first and third refrigerant flow paths to stir the refrigerant flowing therein.

6. The information processing apparatus of claim 5, wherein the stirring structure in the first refrigerant flow path is located at an upstream side of refrigerant flow of each of the connection flow paths, and
the stirring structure in the third refrigerant flow path is located at a downstream side of the refrigerant flow of each of the connection flow paths.

7. The information processing apparatus of claim 5, wherein the stirring structure includes a throttle portion configured to reduce a sectional area of the refrigerant flow path.

8. The information processing apparatus of claim 5, wherein the stirring structure includes a protrusion configured to protrude into the refrigerant flow path.

9. The information processing apparatus of claim 5, wherein the stirring structure includes a twist structure obtained by twisting the refrigerant flow path.

10. The information processing apparatus of claim 1, wherein a thermal sheet is provided between the first refrigerant flow path and the first group of heating components, between the heat exchange modules and the second group of heating components, and between the third refrigerant flow path and the third group of heating components.

11. The information processing apparatus of claim 1, wherein the first group of heating components includes an optical interface element, the second group of heating components includes a CPU, and the third group of heating components includes a power element.

12. The information processing apparatus of claim 1, wherein the first group of heating components has a heating range from 15W to 25W, and a use temperature condition from 20° C. to 40° C.,
the second group of heating components has a heating range from 200 to 300W, and a use temperature condition from 20° C. to 60° C., and
the third group of heating components has a heating range from 15W to 25W, and a use temperature condition from 20° C. to 80° C.
